(19) United States
(12) Patent Application Publication
(10) Pub. No.: US 2025/0228137 A1
(43) Pub. Date: Jul. 10, 2025

(54) SOT-MRAM MEMORY CELL AND METHOD OF MANUFACTURING SOT-MRAM MEMORY CELL

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Jianfeng GAO, Beijing (CN); Meiyin YANG, Beijing (CN); Weibing LIU, Beijing (CN); Tao YANG, Beijing (CN); Junfeng LI, Beijing (CN); Jun LUO, Beijing (CN)

(21) Appl. No.: 18/982,111

(22) Filed: Dec. 16, 2024

(30) Foreign Application Priority Data
Jan. 9, 2024 (CN) 202410032913.5

(51) Int. Cl. H10N 50/10; H10B 61/00; H10N 50/01; H10N 50/20; H10N 50/85

(52) U.S. Cl. CPC H10N 50/10; H10B 61/00; H10N 50/01; H10N 50/20; H10N 50/85

(57) ABSTRACT

The present disclosure relates to the field of microelectronic manufacturing technology, in particular to a SOT-MRAM memory cell and a method of manufacturing a SOT-MRAM memory cell. The SOT-MRAM memory cell includes a bottom electrode layer, a magnetic tunnel junction, an antiferromagnetic layer and a top electrode layer provided sequentially from bottom to top, where the magnetic tunnel junction includes a free layer, a tunneling layer and a pinning layer, the bottom electrode layer is a stack of odd number of layers, and the odd number of layers include at least one W metal layer and at least one Ta metal layer.

### CROSS REFERENCE TO RELATED APPLICATION

This application claims priority to Chinese Patent Application No. 202410032913.5, filed on Jan. 9, 2024, the entire content of which is incorporated herein in its entirety by reference.

### TECHNICAL FIELD

The present disclosure relates to the field of microelectronic manufacturing technology, in particular to a SOT-MRAM memory cell and a method of manufacturing a SOT-MRAM memory cell.

### BACKGROUND

In recent years, Magnetic Random Access Memory (MRAM) using a magnetoresistance effect of a magnetic tunnel junction (MTJ) is considered as a solid-state non-volatile memory in the future, which has the characteristics of high-speed reading and writing, large capacity and low energy consumption. A ferromagnetic MTJ usually has a sandwich structure, including: a magnetic memory layer which may change a magnetization direction to record different data; a tunnel barrier layer which is insulated and located in the middle; and a magnetic reference layer located on the other side of the tunnel barrier layer and having a magnetization direction unchanged.

Spin Orbit Torque-Magnetic Random Access Memory (SOT-MRAM) has the advantages of non-volatility, data writing ability with high speed and low power consumption, and high endurance. SOT-MRAM is gradually becoming a new generation of random access memory after Spin Transfer Torque-Magnetic Random Access Memory (STT-MRAM). In addition, SOT-MRAM is expected to become a key technology to break through the power consumption bottleneck of integrated circuits in the post-Moore era.

SOT-MRAM may produce a strong Spin Orbit Coupling (SOC) effect that switches a heavy metal layer due to a spin orbit moment effect. Therefore, SOT is often needed to have a high spin-charge conversion efficiency, so as to improve a switching efficiency of the SOT-MRAM; it is also needed to have a high spin conductivity, so as to reduce the power loss caused by an excessively large resistivity during the use of SOT-MRAM devices.

However, in the related art, the spin Hall angle of a spin orbit coupling layer material is small, that is, the conversion efficiency between a current and a spin current is low, and the energy loss is large. This results in that a generated spin current is too small to induce a magnetic moment of a magnetic free layer to switch, leading to a decrease in a reading speed. A topological insulator with a large spin Hall angle has a large spin Hall effect, but a low conductivity. Therefore, it is a technical difficulty for SOT-MRAM to improve its switching efficiency and reduce its resistivity.

### SUMMARY

The objective of the present disclosure is to provide a SOT-MRAM memory cell and a method of manufacturing a SOT-MRAM memory cell.

The present disclosure provides a SOT-MRAM memory cell, including: a bottom electrode layer, a magnetic tunnel junction, an antiferromagnetic layer and a top electrode layer provided sequentially from bottom to top, where the magnetic tunnel junction includes a free layer, a tunneling layer and a pinning layer, the bottom electrode layer is a stack of odd number of layers, and the odd number of layers include at least one W metal layer and at least one Ta metal layer.

According to the technical solution of the present disclosure, preferably, a thickness of the bottom electrode layer is in a range of 3.25 nm to 8.5 nm, where a thickness ratio of the at least one W metal layer and the at least one Ta metal layer in the bottom electrode layer is 1:(0.18-0.38), and one of the at least one W metal layer is provided on a side of the bottom electrode layer close to a substrate wafer.

For example, the bottom electrode layer includes 3 layers, and a total thickness of the bottom electrode layer is 3.25 nm. Specifically, a thickness of the W metal layer on a side close to the substrate wafer is 1.25 nm, a thickness of the Ta metal layer in the middle is 0.5 nm, and a thickness of the uppermost W metal layer is 1.25 nm.

For example, the bottom electrode layer includes 5 layers, and the total thickness of the bottom electrode layer is 5 nm. Specifically, along a direction extending from the substrate wafer to the top electrode layer, the bottom electrode layer includes a W metal layer (with a thickness of 1.25 nm), a Ta metal layer (with a thickness of 0.5 nm), a W metal layer (with a thickness of 1.25 nm), a Ta metal layer (with a thickness of 0.5 nm), and a W metal layer (with a thickness of 1.5 nm) in sequence.

For example, the bottom electrode layer includes 7 layers, and the total thickness of the bottom electrode layer is 6.75 nm. Specifically, along a direction extending from the substrate wafer to the top electrode layer, the bottom electrode layer includes a W metal layer (with a thickness of 1.25 nm), a Ta metal layer (with a thickness of 0.5 nm), a W metal layer (with a thickness of 1.25 nm), a Ta metal layer (with a thickness of 0.5 nm), a W metal layer (with a thickness of 1.25 nm), a Ta metal layer (with a thickness of 0.5 nm), and a W metal layer (with a thickness of 1.5 nm) in sequence.

For example, the bottom electrode layer includes 9 layers, and the total thickness of the bottom electrode layer is 8.5 nm. Specifically, along a direction extending from the substrate wafer to the top electrode layer, the bottom electrode layer includes a W metal layer (with a thickness of 1.25 nm), a Ta metal layer (with a thickness of 0.5 nm), a W metal layer (with a thickness of 1.25 nm), a Ta metal layer (with a thickness of 0.5 nm), a W metal layer (with a thickness of 1.25 nm), a Ta metal layer (with a thickness of 0.5 nm), a W metal layer (with a thickness of 1.25 nm), a Ta metal layer (with a thickness of 0.5 nm), and a W metal layer (with a thickness of 1.5 nm) in sequence.

According to the technical solution of the present disclosure, preferably, the free layer includes a CoFeB alloy layer, the tunneling layer includes a MgO layer, the pinning layer includes a CoFeB alloy layer, and the top electrode layer includes a Ta metal layer and a Ru metal layer.

According to the technical solution of the present disclosure, preferably, the antiferromagnetic layer includes a W metal layer, a Co metal layer, a Pt metal layer and a Ru metal layer.

According to the technical solution of the present disclosure, preferably, the memory cell further includes a substrate wafer and a protective layer, where the substrate wafer, the bottom electrode layer, the free layer, the tunneling layer, the pinning layer, the antiferromagnetic layer, the top electrode layer and the protective layer are sequentially provided from bottom to top, and the protective layer is SiN.

According to the technical solution of the present disclosure, preferably, the free layer is CoFeB, the tunneling layer is MgO, the pinning layer is CoFeB, the top electrode layer is Ta/Ru and a Ta layer, and the antiferromagnetic layer is W/Co/[Pt/Co]ₘPt/Co/Ru/Co/[Pt/Co]ₙPt, where [Pt/Co]ₘ represents that a Pt/Co layer is repeated m times, m is in a range of 1 to 4, and n in [Pt/Co]ₙ is in a range of 4 to 8.

In a second aspect, the present disclosure further provides a method of manufacturing the above SOT-MRAM memory cell, including:
step S1: sequentially forming the bottom electrode layer, the free layer, the tunneling layer, the pinning layer, the antiferromagnetic layer, the top electrode layer and a hard mask layer on a substrate wafer;
step S2: transferring a pattern onto the hard mask layer through photolithography and etching;
step S3: etching the top electrode layer by using the hard mask layer as a mask;
step S4: etching the antiferromagnetic layer and the pinning layer by using the top electrode layer as a mask, and stopping the etching on a surface of the tunneling layer;
step S5: depositing a protective layer; and
step S6: patterning the bottom electrode layer through photolithography and etching.

According to the technical solution of the present disclosure, preferably, in the step S1, a chemical mechanical polishing is performed first on the substrate wafer so that a roughness Ra value of the substrate wafer is less than 0.3 nm, and then the bottom electrode layer is formed by a sputtering deposition, where a degassing is performed before the sputtering deposition, and a temperature is controlled to be in a range of 250° C. to 300° C. for a period in a range of 20 s to 60 s during the degassing.

According to the technical solution of the present disclosure, preferably, in the step S4, the antiferromagnetic layer and the pinning layer are etched by using an ion beam, a direction angle of the ion beam is in a range of 30° to 60°, an energy is in a range of 50 V to 200 V, and a protective gas is argon.

### BRIEF DESCRIPTION OF THE DRAWINGS

In order to more clearly explain the technical solutions in the embodiments of the present disclosure or in the related art, the drawings required in the description of the embodiments or the related art will be briefly introduced below. Obviously, the drawings in the following description are only some embodiments of the present disclosure. For those of ordinary skill in the art, other drawings may be obtained based on these drawings without exerting any creative effort.

FIG. 1 is a schematic diagram of a spin current conversion rate of an alloy material with different W/Ta thickness ratios in the present disclosure;

FIG. 2 is a schematic diagram of a resistivity of an alloy material with different W/Ta thickness ratios in the present disclosure;

FIG. 3 is a schematic diagram of a structure of a SOT-MRAM memory cell in the present disclosure;

FIG. 4 is a schematic diagram of step S1 in a method of manufacturing the SOT-MRAM memory cell in the present disclosure;

FIG. 5 is a schematic diagram of step S2 in a method of manufacturing the SOT-MRAM memory cell in the present disclosure;

FIG. 6 is a schematic diagram of step S3 in a method of manufacturing the SOT-MRAM memory cell in the present disclosure;

FIG. 7 is a schematic diagram of step S4 in a method of manufacturing the SOT-MRAM memory cell in the present disclosure;

FIG. 8 is a schematic diagram of step S5 in a method of manufacturing the SOT-MRAM memory cell in the present disclosure;

FIG. 9 is a schematic diagram of step S6 in a method of manufacturing the SOT-MRAM memory cell in the present disclosure.

Reference numerals: 1: Substrate wafer; 2: Bottom electrode layer; 3: Free layer; 4: Tunneling layer; 5: Pinning layer; 6: Antiferromagnetic layer; 7: Top electrode layer; 8: Ta layer; 9: SOC layer; 10: SOG layer; 11: Protective layer.

### DETAILED DESCRIPTION OF EMBODIMENTS

It should be noted that the following detailed description is exemplary and is intended to provide further explanation for the present disclosure. Unless otherwise specified, all technical and scientific terms used herein have the same meanings as commonly understood by those of ordinary skill in the technical field to which the present disclosure pertains.

It should be noted that the terminology used here is only for describing specific embodiments, and is not intended to limit the exemplary embodiments according to the present disclosure. As used herein, unless the context clearly indicates otherwise, a singular form also includes a plural form. Additionally, it should also be understood that when the term “contain” and/or the term “include” are used in the present disclosure, they specify the presence of a feature, a step, an operation, a device, a component and/or a combination thereof.

The technical solution of the present disclosure will be described clearly and completely with the embodiments below. Obviously, the described embodiments are a part of the embodiments of the present disclosure, and not all embodiments. Based on the embodiments of the present disclosure, all the other embodiments obtained by those of ordinary skill in the art without any creative effort are within the protection scope of the present disclosure.

### Embodiment 1

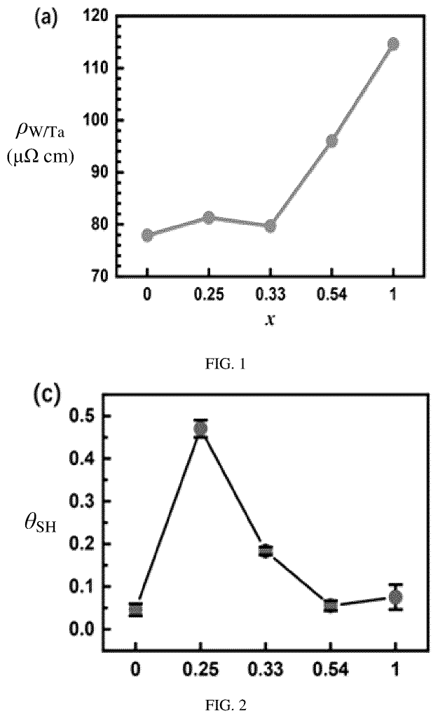

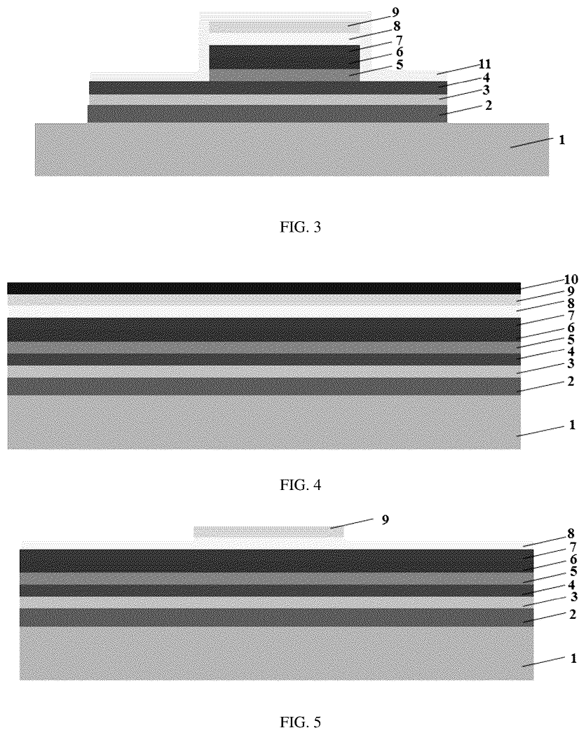

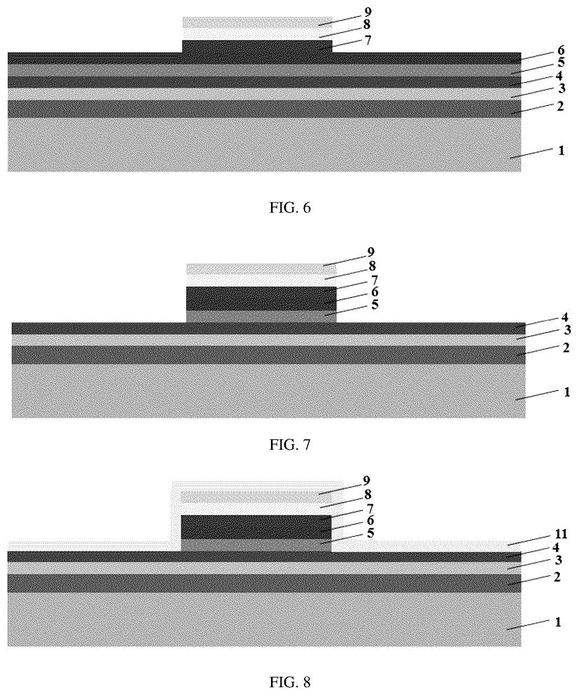

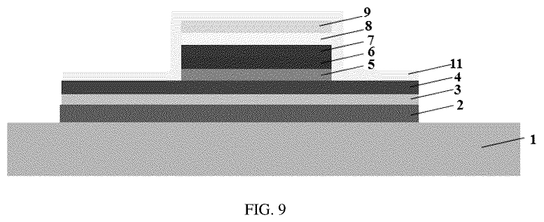

As shown in FIG. 1 to FIG. 6, this embodiment provides a SOT-MRAM memory cell, including: a bottom electrode layer 2, a magnetic tunnel junction, an antiferromagnetic layer 6 and a top electrode layer 7 provided sequentially from bottom to top. The magnetic tunnel junction includes a free layer 3, a tunneling layer 4 and a pinning layer 5. The bottom electrode layer 2 is a stack of odd number of layers, and the odd number of layers include at least one W metal layer and at least one Ta metal layer.

The bottom electrode layer 2 of the present disclosure is a stack structure having odd number of layers. Researches show that it has a high spin Hall angle, a low resistance, and a high conversion efficiency between a current and a spin current, and the generated spin current perpendicular to the current direction is high, so that a spin orbit coupling layer may quickly switch the magnetization direction of the magnetic free layer 3 to improve the reading speed. Therefore, an average value of the tunnel junction TMR of the SOT-MRAM memory cell in the present disclosure may be more than 100%.

On the basis of the above technical solution, further, a thickness ratio of the at least one W metal layer and the at least one Ta metal layer in the bottom electrode layer 2 is 1:(0.18-0.38), and one of the at least one W metal layer is provided on a side of the bottom electrode layer 2 close to a substrate wafer 1.

For example, when 5 layers are deposited for the bottom electrode layer 2 and the thickness of the bottom electrode layer 2 is 5 nm, the thickness ratio of the W metal layer and the Ta metal layer in the bottom electrode layer 2 is 1:0.25, and the deposition manner is as follows:
First, a W metal layer with a thickness of 1.25 nm is deposited for the bottom electrode layer 2 through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Then, a W metal layer with a thickness of 1.25 nm is deposited through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Finally, a W metal layer with a thickness of 1.5 nm is deposited through a plurality of depositions; typically a W metal layer with a thickness of 0.25 nm is deposited for each deposition and the deposition is performed 6 times.

For example, when 3 layers are deposited for the bottom electrode layer 2 and the thickness of the bottom electrode layer 2 is 3.25 nm, the thickness ratio of the W metal layer and the Ta metal layer in the bottom electrode layer 2 is 1:0.18, and the deposition manner is as follows:
First, a W metal layer with a thickness of 1.25 nm is deposited for the bottom electrode layer 2 through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Finally, a W metal layer with a thickness of 1.5 nm is deposited through a plurality of depositions; typically a W metal layer with a thickness of 0.25 nm is deposited for each deposition and the deposition is performed 6 times.

For example, when 7 layers are deposited for the bottom electrode layer 2 and the thickness of the bottom electrode layer 2 is 6.75 nm, the thickness ratio of the W metal layer and the Ta metal layer in the bottom electrode layer 2 is 1:0.28, and the deposition manner is as follows:
First, a W metal layer with a thickness of 1.25 nm is deposited for the bottom electrode layer 2 through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Then, a W metal layer with a thickness of 1.25 nm is deposited through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Then, a W metal layer with a thickness of 1.25 nm is deposited through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Finally, a W metal layer with a thickness of 1.5 nm is deposited through a plurality of depositions; typically a W metal layer with a thickness of 0.25 nm is deposited for each deposition and the deposition is performed 6 times.

For example, when 9 layers are deposited for the bottom electrode layer 2 and the thickness of the bottom electrode layer 2 is 8.5 nm, the thickness ratio of the W metal layer and the Ta metal layer in the bottom electrode layer 2 is 1:0.38, and the deposition manner is as follows:
First, a W metal layer with a thickness of 1.25 nm is deposited for the bottom electrode layer 2 through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Then, a W metal layer with a thickness of 1.25 nm is deposited through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Then, a W metal layer with a thickness of 1.25 nm is deposited through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Then, a W metal layer with a thickness of 1.25 nm is deposited through a plurality of depositions; typically a W metal layer with a thickness of 0.25 nm is deposited for each deposition and the deposition is performed 5 times.
Then, a Ta metal layer with a thickness of 0.5 nm is deposited through a plurality of depositions; typically a Ta metal layer with a thickness of 0.25 nm is deposited for each deposition and the deposition is performed 2 times.
Finally, a W metal layer with a thickness of 1.5 nm is deposited through a plurality of depositions; typically a W metal layer with a thickness of 0.25 nm is deposited for each deposition and the deposition is performed 6 times.

The free layer 3 includes a CoFeB alloy layer, the tunneling layer 4 includes a MgO layer, the pinning layer 5 includes a CoFeB alloy layer, the top electrode layer 7 includes a Ta metal layer and a Ru metal layer, and the antiferromagnetic layer 6 includes a W metal layer, a Co metal layer, a Pt metal layer and a Ru metal layer.

Preferably, the free layer 3 is CoFeB, the tunneling layer 4 is MgO, the pinning layer 5 is CoFeB, the top electrode layer 7 is Ta/Ru and a Ta layer 8, and the antiferromagnetic layer 6 is W/Co/[Pt/Co]ₘPt/Co/Ru/Co/[Pt/Co]ₙPt, where [Pt/Co]ₘ represents that a Pt/Co layer is repeated m times, m is in a range of 1 to 4, and n in [Pt/Co]ₙ is in a range of 4 to 8.

Preferably, the thickness of each layer is as follows: the free layer 3 is CoFeB(1.0), the tunneling layer 4 is MgO(1.2), the pinning layer 5 is CoFeB(1.2), the top electrode layer 7 is Ta(3)/Ru(4) and the Ta layer 8(100), the antiferromagnetic layer 6 is W(0.65-0.75)/Co(0.55-0.65)/[Pt(0.75)/Co(0.4)]_{2- 4}Pt(0.75)/Co(0.6)/Ru(0.7)/Co(0.6)/[Pt(0.75)/Co(0.35-0.45)]₅₋₇Pt(0.7-0.8), and the unit of thickness is nm.

In this embodiment, specifically, the SOT-MRAM memory cell includes a substrate wafer 1, a bottom electrode layer 2, a free layer 3, a tunneling layer 4, a pinning layer 5, an antiferromagnetic layer 6, a top electrode layer 7 and a protective layer 11 provided sequentially from bottom to top, where the protective layer 11 is SiN.

In the present disclosure, a stack structure in which W and Ta are provided and having odd number of layers is used as the bottom electrode layer 2, which has a high spin Hall angle, a low resistance, and a high conversion efficiency between a current and a spin current, and the generated spin current perpendicular to the current direction is high, so that a spin orbit coupling layer may quickly switch the magnetization direction of the magnetic free layer 3 to improve the reading speed.

In the present disclosure, the free layer is CoFeB, the tunneling layer is MgO, the pinning layer is CoFeB, the antiferromagnetic layer is W/Co/[Pt/Co]ₘPt/Co/Ru/Co/[Pt/Co]ₙPt, and the top electrode layer is Ta 3 nm/Ru 4 nm. Moreover, the stack film is deposited on the bottom electrode with W as a surface interface, so as to achieve a perpendicular magnetic anisotropy of the free layer, the pinning layer and the antiferromagnetic layer, and achieve a ferromagnetic coupling of the pinning layer and the antiferromagnetic layer.

Therefore, under the interaction of various layer structures above, an average value of the tunnel junction TMR of the SOT-MRAM memory cell in the present disclosure may be more than 100%.

### Embodiment 2

As shown in FIG. 1 to FIG. 6, this embodiment provides a method of manufacturing a SOT-MRAM memory cell, including the following steps S1 to S6.

In step S1, a bottom electrode layer 2, a free layer 3, a tunneling layer 4, a pinning layer 5, an antiferromagnetic layer 6, a top electrode layer 7 and a hard mask layer are formed sequentially on a substrate wafer 1.

The specific structure is: W/Ta/CoFeB(1.0)/MgO(1.2)/CoFeB(1.2)/W(0.7)/Co(0.6)/[Pt(0.75)/Co(0.4)]_{2- 4}Pt(0.75)/Co(0.6)/Ru(0.7)/Co(0.6)/[Pt(0.75)/Co(0.4)]₅₋₇Pt(0.75)Ta(3)/Ru(4)/Ta(100)/SOC(80)/SOG(80).

Specifically, W/Ta is the bottom electrode layer 2, 5 layers are deposited for the bottom electrode layer 2, and the thickness of the bottom electrode layer 2 is 5 nm. The thickness ratio of the W metal layer and the Ta metal layer in the bottom electrode layer 2 is 1:0.25, and the deposition thereof is performed with reference to the deposition manner in the Embodiment 1. In addition, CoFeB(1.0) is the free layer 3; MgO(1.2) is the tunneling layer 4; CoFeB(1.2) is the pinning layer 5; W(0.7)/Co(0.6)/[Pt(0.75)/Co(0.4)]₂₋₄Pt(0.75)/Co(0.6)/Ru(0.7)/Co(0.6)/[Pt(0.75)/Co(0.4)]₅₋₇Pt(0.75) is the antiferromagnetic layer 6; Ta(3)/Ru(4)/Ta(100) is the top electrode layer 7 which also serves as the metal hard mask layer; SOC(80)/SOG 80) is the hard mask layer; and the unit is nm.

In step S2, a pattern is transferred onto the hard mask layer through photolithography and etching.

The specific process of step S2 is as follows.

First, a SOG layer 10 is etched by using a photoresist as a mask, where the etching temperature is room temperature, the pressure is 65 mTorr, the etching gas is Ar, CHF₃ and CF₄, the flow rate of Ar is 200 sccm, the flow rate of CHF₃ is 5 sccm, and the flow rate of CF₄ is 35 sccm; the 27 MHz radio frequency power supply is 300 W; and the 2 MHz radio frequency power supply is 100 W.

Then, a SOC layer 9 is etched by using the SOG layer 10 as a mask, where the etching temperature is room temperature, the pressure is 10 mTorr, the etching gas is Ar, O₂ and CH₄, the flow rate of Ar is 200 sccm, the flow rate of O₂ is 50 sccm, and the flow rate of CH₄ is 20 sccm; the radio frequency power supply is 250 W; and the bias power supply is 150 W.

Finally, the SOG layer 10 is removed by using wet BOE.

In step S3, the top electrode layer 7 is etched by using the SOC layer 9 as a mask, and the etching is stopped at a surface of the antiferromagnetic layer 6.

The specific process of step S3 is as follows:

First, a reaction interface between the SOC layer 9 and the Ta layer is removed, and the conditions are as follows: the temperature is 40° C., the pressure is 10 mTorr, the etching gas is O₂ and CF₄, the flow rate of O₂ is 5 sccm, the flow rate of CF₄ is 100 sccm, the radio frequency power supply is 300 W, the bias power supply is 35 W, and the etching period is 20 seconds.

Then, the top electrode layer 7 is etched, and the conditions are as follows: the temperature is 40° C., the pressure is 10 mTorr, the etching gas is Ar, Cl₂ and CH₂F₂, the flow rate of Ar is 200 sccm, the flow rate of Cl₂ is 38 sccm, the flow rate of CH₂F₂ is 100 sccm, the radio frequency power supply is 200 W, the bias power supply is 35 W, and the etching period is 20 seconds.

In step S4, the antiferromagnetic layer 6 and the pinning layer 5 are etched by using the top electrode layer 7 as a mask, and the etching is stopped at a surface of the tunneling layer 4.

The specific process of step S4 is as follows:

An ion beam etching is used for etching, the direction angle of the ion beam is 50°, the energy is 100 V, and the protective gas is argon.

In step S5, SiN is deposited at low temperature to form a protective layer 11.

In step S6, the bottom electrode layer 2 is patterned through photolithography and etching.

Finally, the top electrode and the bottom electrode are interconnected. For example, the interconnection process of the top electrode and the bottom electrode is completed using a conventional process.

The magnetic tunnel junction TMR of the SOT-MRAM prepared in the present embodiment is 110%.

### Embodiment 3

The difference between the present embodiment and the Embodiment 2 is: 3 layers are deposited for the bottom electrode layer 2, the thickness of the bottom electrode layer 2 is 3.25 nm, and the thickness ratio of the W metal layer and the Ta metal layer in the bottom electrode layer 2 is 1:0.18.

Other steps and parameters are basically the same as those in the Embodiment 2.

The magnetic tunnel junction TMR of the SOT-MRAM prepared in the present embodiment is 105%.

### Embodiment 4

The difference between the present embodiment and the Embodiment 2 is: 7 layers are deposited for the bottom electrode layer 2, the thickness of the bottom electrode layer 2 is 6.75 nm, and the thickness ratio of the W metal layer and the Ta metal layer in the bottom electrode layer 2 is 1:0.28.

Other steps and parameters are basically the same as those in the Embodiment 2.

The magnetic tunnel junction TMR of the SOT-MRAM prepared in the present embodiment is 110%.

### Embodiment 5

The difference between the present embodiment and the Embodiment 2 is: 9 layers are deposited for the bottom electrode layer 2, the thickness of the bottom electrode layer 2 is 8.5 nm, and the thickness ratio of the W metal layer and the Ta metal layer in the bottom electrode layer 2 is 1:0.38.

Other steps and parameters are basically the same as those in the Embodiment 2.

The magnetic tunnel junction TMR of the SOT-MRAM prepared in the present embodiment is 114%.

Researches show that the selection of the thickness ratio of W and Ta of the bottom electrode layer in the present disclosure takes into account the needs of a spin orbit coupling layer material for both a high spin current conversion rate and a low resistivity.

In summary, the tunnel junction TMR value of the SOT-MRAM memory cell prepared in the present disclosure may be more than 100%. Combined with the characteristics of non-volatility, data writing ability with high speed and low power consumption, and high device durability, the SOT-MRAM memory cell in the present disclosure may be used as a new generation of random access memory after STT-MRAM.

The SOT-MRAM memory cell of the present disclosure at least has the following technical effects:

In the present disclosure, a stack structure in which W and Ta are provided and having odd number of layers is used as the bottom electrode layer, which has a high spin Hall angle, a low resistance, and a high conversion efficiency between a current and a spin current, and the generated spin current perpendicular to the current direction is high, so that a spin orbit coupling layer may quickly switch the magnetization direction of the magnetic free layer to improve the reading speed.

In the present disclosure, the free layer is CoFeB, the tunneling layer is MgO, the pinning layer is CoFeB, the antiferromagnetic layer is W/Co/[Pt/Co]ₘPt/Co/Ru/Co/[Pt/Co]ₙPt, and the top electrode layer is Ta/Ru. Moreover, the stack film is deposited on the bottom electrode with W as a surface interface, so as to achieve a perpendicular magnetic anisotropy of the free layer, the pinning layer and the antiferromagnetic layer, and achieve a ferromagnetic coupling of the pinning layer and the antiferromagnetic layer.

Therefore, under the interaction of various layer structures above, an average value of the tunnel junction TMR of the SOT-MRAM memory cell in the present disclosure may be more than 100%.

Finally, it should be noted that the above embodiments are only used to illustrate the technical solutions of the present disclosure, rather than limit the present disclosure. Although the present disclosure has been described in detail with reference to the above embodiments, those skilled in the art should understand that modifications may still be performed to the technical solutions described in the above embodiments, or equivalent replacements may be performed to some or all of the technical features. However, these modifications or replacements do not make the essence of the corresponding technical solution deviate from the scope of the technical solutions of various embodiments of the present disclosure.

What is claimed is:

1. A SOT-MRAM memory cell, comprising:
a bottom electrode layer, a magnetic tunnel junction, an antiferromagnetic layer and a top electrode layer provided sequentially from bottom to top,
wherein the magnetic tunnel junction comprises a free layer, a tunneling layer and a pinning layer, the bottom electrode layer is a stack of odd number of layers, and the odd number of layers comprise at least one W metal layer and at least one Ta metal layer.

2. The SOT-MRAM memory cell according to claim 1, wherein a thickness of the bottom electrode layer is in a range of 3.25 nm to 8.5 nm.

3. The SOT-MRAM memory cell according to claim 1, wherein a thickness ratio of the at least one W metal layer and the at least one Ta metal layer in the bottom electrode layer is 1:(0.18-0.38), and one of the at least one W metal layer is provided on a side of the bottom electrode layer close to a substrate wafer.

4. The SOT-MRAM memory cell according to claim 1, wherein the free layer comprises a CoFeB alloy layer, the tunneling layer comprises a MgO layer, the pinning layer comprises a CoFeB alloy layer, and the top electrode layer comprises a Ta metal layer and a Ru metal layer.

5. The SOT-MRAM memory cell according to claim 1, wherein the antiferromagnetic layer comprises a W metal layer, a Co metal layer, a Pt metal layer and a Ru metal layer.

6. The SOT-MRAM memory cell according to claim 1, further comprising:
a substrate wafer and a protective layer,
wherein the substrate wafer, the bottom electrode layer, the free layer, the tunneling layer, the pinning layer, the antiferromagnetic layer, the top electrode layer and the protective layer are sequentially provided from bottom to top, and the protective layer is SiN.

7. The SOT-MRAM memory cell according to claim 1,
wherein the free layer is CoFeB, the tunneling layer is MgO, the pinning layer is CoFeB, the top electrode layer is Ta/Ru and a Ta layer, and the antiferromagnetic layer is W/Co/[Pt/Co]ₘPt/Co/Ru/Co/[Pt/Co]ₙPt, and
wherein [Pt/Co]ₘ represents that a Pt/Co layer is repeated m times, m is in a range of 1 to 4, and n in [Pt/Co]ₙ is in a range of 4 to 8.

8. A method of manufacturing the SOT-MRAM memory cell according to claim 1, comprising:
step S1: sequentially forming the bottom electrode layer, the free layer, the tunneling layer, the pinning layer, the antiferromagnetic layer, the top electrode layer and a hard mask layer on a substrate wafer;
step S2: transferring a pattern onto the hard mask layer through photolithography and etching;
step S3: etching the top electrode layer by using the hard mask layer as a mask;
step S4: etching the antiferromagnetic layer and the pinning layer by using the top electrode layer as a mask, and stopping the etching on a surface of the tunneling layer;
step S5: depositing a protective layer; and
step S6: patterning the bottom electrode layer through photolithography and etching.

9. The method according to claim 8, wherein in the step S1, a chemical mechanical polishing is performed first on the substrate wafer so that a roughness Ra value of the substrate wafer is less than 0.3 nm, and then the bottom electrode layer is formed by a sputtering deposition; and
wherein a degassing is performed before the sputtering deposition, and a temperature is controlled to be in a range of 250° C. to 300° C. for a period in a range of 20 s to 60 s during the degassing.

10. The method according to claim 8, wherein in the step S4, the antiferromagnetic layer and the pinning layer are etched by using an ion beam, a direction angle of the ion beam is in a range of 30° to 60°, an energy is in a range of 50 V to 200 V, and a protective gas is argon.
